(19) United States
(12) Patent Application Publication
(10) Pub. No.: US 2026/0100661 A1
(43) Pub. Date: Apr. 9, 2026

(54) ELECTRICAL ADHESIVE DEVICE, METHOD FOR MANUFACTURING SAME, AND ELECTROSTATIC CLUTCH COMPRISING SAME

(71) Applicant: SOGANG UNIVERSITY RESEARCH & BUSINESS DEVELOPMENT FOUNDATION, Seoul (KR)

(72) Inventors: Hyeong Jun KIM, Incheon (KR); Se Hwan PARK, Seoul (KR)

(73) Assignee: SOGANG UNIVERSITY RESEARCH & BUSINESS DEVELOPMENT FOUNDATION, Seoul (KR)

(21) Appl. No.: 19/346,794

(22) Filed: Oct. 1, 2025

(30) Foreign Application Priority Data
Oct. 7, 2024 (KR) 10-2024-0135335
Sep. 4, 2025 (KR) 10-2025-0125653

(51) Int. Cl. H02N 13/00; B01J 39/18; B01J 41/12; B01J 47/12; H01L 21/683

(52) U.S. Cl. CPC H02N 13/00; B01J 39/18; B01J 41/12; B01J 47/12; H10P 72/722

(57) ABSTRACT

The present disclosure relates to an electroadhesive device, a method for manufacturing the same, and an electrostatic clutch comprising the same, and more specifically, to an electroadhesive device capable of being applied to various fields, such as an electrostatic clutch, by freely controlling electrostatic attraction even at low operating voltages through the application of a polyanionic ionomer and a polycationic ionomer in a heterojunction structure, a method for manufacturing the same, and an electrostatic clutch comprising the same.

### BACKGROUND

### 1. Technical Field

The present disclosure claims priority to and the benefits of Korean Patent Application No. 10-2024-0135335 and 10-2025-0125653, filed with the Korean Intellectual Property Office on Oct. 7, 2024 and Sep. 4, 2025, the entire contents of which are incorporated herein by reference.

The present disclosure relates to an electroadhesive device, a method for manufacturing the same, and an electrostatic clutch including the same, and more specifically, to an electroadhesive device capable of being applied to various fields, such as an electrostatic clutch, by freely controlling electrostatic attraction even at low operating voltages, a method for manufacturing the same, and an electrostatic clutch including the same.

### 2. Related Art

Materials capable of dynamically adjusting their rigidity or stiffness in response to external stimuli are of significant interest in the fields of robotics, biomedicine, and haptics.

In particular, electrically activated electroadhesive devices can be applied to various applications such as AR/VR haptic devices, soft exoskeletons, zipping actuators, and grippers, which require fast and reversible switching through the bonding and debonding of materials with different rigidity.

Conventional electroadhesive devices are based on a structure in which a dielectric material is sandwiched between two electrodes. When a strong electric field is applied to this structure, one side becomes charged with a positive (+) charge and the other side with a negative (−) charge, so that the structure acts like a capacitor. At this time, when an electrostatic attraction acts between different electrodes, it is called electroadhesion.

A representative application utilizing this electroadhesion is an electrostatic clutch. When configured in the form of the electrostatic clutch, it is possible to induce rigidity switching between materials having different rigidity. The electrostatic clutch has a structure in which a tensile force is applied in a horizontal direction in a structure in which a dielectric material is sandwiched between electrodes. This allows the clutch structure to either slide smoothly or remain in a coupled state without slipping, depending on the applied voltage. In this way, the rigidity of the material can be programmed.

However, in the case of a structure in which a single dielectric material is sandwiched between electrodes as in the related art, there is a problem in that a very large voltage needs to be applied in general. If a defect in the dielectric material occurs due to an external impact, a large-intensity current leakage may occur, potentially causing serious damage to the product or human body. In addition, there is a significant disadvantage in terms of energy efficiency in that additional devices such as voltage amplifiers need to be introduced together and a device for shielding current or a complex circuit needs to be installed together. Furthermore, there are also problems such as incompatibility with other electronic devices and limited portability.

Therefore, in order to address the aforementioned problems, the present inventors have recognized that it is urgent to develop a device applicable to clutches and the like capable of operating even at low operating voltages, thereby completing the present disclosure. [Prior Art Documents]

### PATENT DOCUMENTS

(Patent Document 1) Korean Patent No. 10-2515029
(Patent Document 2) Korean Patent Laid-Open Publication No. 10-2024-0057370

### SUMMARY

An object of the present disclosure is to provide an electroadhesive device that can be applied to various fields, such as clutches, by freely controlling electrostatic attraction even at low operating voltages, and a method for manufacturing the same.

Another object of the present disclosure is to provide a low-voltage electrostatic clutch having low adhesion and mechanical robustness that appear in reverse bias by freely controlling electrostatic attraction even at low operating voltages.

In order to achieve the above objects, according to one aspect of the present disclosure, there is provided an electroadhesive device including: an anion exchange membrane including a polycationic ionomer; a first electrode formed on one surface of the anion exchange membrane; a cation exchange membrane including a polyanionic ionomer; and a second electrode formed on one surface of the cation exchange membrane, wherein the other surface of the anion exchange membrane and the other surface of the cation exchange membrane are joined to each other to form a heterojunction structure.

In addition, according to another aspect of the present disclosure, there is provided a method for manufacturing an electroadhesive device, the method including the steps of: forming a first electrode on one surface of an anion exchange membrane; forming a second electrode on one surface of a cation exchange membrane; and joining the other surface of the anion exchange membrane and the other surface of the cation exchange membrane to each other.

Furthermore, according to still another aspect of the present disclosure, there is provided an electrostatic clutch including: the above electroadhesive device; substrates positioned on both surfaces of the electroadhesive device; a tunnel-shaped guide surrounding the substrates; and elastomer layers respectively attached to the upper and lower portions of the guide and stacked on the surfaces of the substrates.

The electroadhesive device according to one embodiment of the present disclosure includes a polyanionic ionomer and a polycationic ionomer in a heterojunction structure, thereby significantly reducing operating voltage.

The method for manufacturing an electroadhesive device according to one embodiment of the present disclosure can form a heterojunction between the polyanionic ionomer and the polycationic ionomer through a simple process.

A clutch employing the electroadhesive device with the heterojunction structure of the polyanionic ionomer and polycationic ionomer according to one embodiment of the present disclosure can exhibit low adhesion and mechanical robustness when a reverse bias voltage is applied, and can adjust rigidity depending on the forward and reverse bias of an electric current.

The effects of the present disclosure are not limited to the effects mentioned above, and effects not mentioned will be clearly understood by those skilled in the art from the present specification and the accompanying drawings.

### BRIEF DESCRIPTION OF THE DRAWINGS

FIG. 1 is an image schematically illustrating an electroadhesive device according to one embodiment of the present disclosure.

FIG. 2 is an image schematically illustrating an electrostatic clutch according to one embodiment of the present disclosure.

FIG. 3 shows images schematically illustrating the operating mechanism of an electrostatic clutch according to one embodiment of the present disclosure.

FIG. 4 shows differential scanning calorimetry (DSC) graphs confirming thermal characteristics of (a) of FIG. 4: a polyanionic ionomer and (b) of FIG. 4: a polycationic ionomer according to one embodiment of the present disclosure.

FIG. 5 shows stress-strain curves confirming mechanical characteristics of (a) of FIG. 5: a polyanionic ionomer and (b) of FIG. 5: a polycationic ionomer according to one embodiment of the present disclosure.

FIG. 6 is a graph confirming the adhesive force of the junction between an anion exchange membrane and a cation exchange membrane according to one embodiment of the present disclosure.

FIG. 7 shows (a) of FIG. 7: Nyquist plots and (b) of FIG. 7: Bode phase angle plots of the measured AC impedance for the heterojunction of ionomers forming an anion exchange membrane and a cation exchange membrane in an electroadhesive device according to one embodiment of the present disclosure.

FIG. 8 is an image confirming a force capacity per unit contact area of an electroadhesive device according to one embodiment of the present disclosure.

FIG. 9 is a force-displacement curve confirming the overall stiffness of an electrostatic clutch according to one embodiment of the present disclosure.

FIG. 10 is a graph showing the results of repetitive lap shear tests confirming the reversibility of an electrostatic clutch according to one embodiment of the present disclosure.

### DETAILED DESCRIPTION

Hereinafter, specific embodiments of the present disclosure will be described in detail with reference to the accompanying drawings.

Throughout the present specification, when a part is described as “including” a certain component, it means that other components may be further included, rather than excluded, unless otherwise specifically stated.

Throughout the present specification, when a member is described as being located “on” another member, it includes not only a case where the member is in contact with the other member, but also a case where a third member exists between the two members.

Throughout the present specification, terms including ordinal numbers, such as “first” and “second”, are used only for the purpose of distinguishing one component from another component, and are not limited by the ordinal numbers.

In describing the principles of preferred embodiments of the present disclosure in detail, if it is determined that a detailed description of a related known function or configuration may unnecessarily obscure the subject matter of the present disclosure, the detailed description thereof will be omitted.

### Electroadhesive Device

According to one aspect of the present disclosure, there is provided an electroadhesive device including: an anion exchange membrane including a polycationic ionomer; a first electrode formed on one surface of the anion exchange membrane; a cation exchange membrane including a polyanionic ionomer; and a second electrode formed on one surface of the cation exchange membrane.

Additionally, in the electroadhesive device of the present disclosure, the other surface of the anion exchange membrane and the other surface of the cation exchange membrane may be joined to each other to form a heterojunction structure.

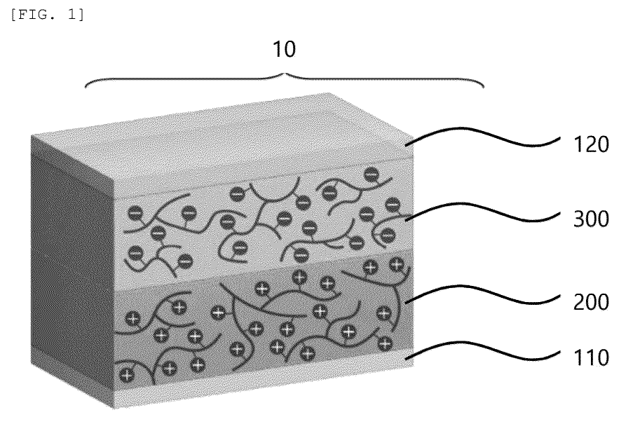

FIG. 1 is an image schematically illustrating an electroadhesive device according to one embodiment of the present disclosure.

As shown in FIG. 1, in the electroadhesive device 10 of the present disclosure, a first electrode 110 is formed on one surface of an anion exchange membrane 200 including a polycationic ionomer, a second electrode 120 is formed on one surface of a cation exchange membrane 300 including a polyanionic ionomer, and the other surfaces of the anion exchange membrane 200 and the cation exchange membrane 300 are joined to each other to form a heterojunction structure.

The terms “polycationic ionomer” or “polyanionic ionomer” as used herein refer to a polymer including a cation- or anion-bearing functional group and the corresponding counter cation or anion in a side chain of the polymer backbone, respectively. In this case, the cationic or anionic functional group may include less than 15 mol % of ionic monomer units among the total monomers.

The anion exchange membrane 200 and the cation exchange membrane 300 are ionomer heterojunctions of oppositely charged polycationic ionomer and polyanionic ionomer, respectively, and have oppositely charged forms, thereby allowing the mechanical robustness and stiffness of the electroadhesive device 10 according to the present disclosure to be controlled.

An adhesive force (Pₚₑₐₖ) of the junction where the anion exchange membrane 200 and the cation exchange membrane 300 are joined may be maintained at 10 mN or less. In this case, the adhesive force (Pₚₑₐₖ) refers to an adhesive force measured at a speed of 0.01 mm/sec using a texture analyzer (TA.XT PlusC, Stable Micro Systems). The polycationic ionomer and the polyanionic ionomer respectively included in the anion exchange membrane 200 and the cation exchange membrane 300 have low van der Waals forces and thus, have high adhesive force at a forward bias applied voltage and low adhesive force at a reverse bias applied voltage, thereby inducing a large stiffness switching.

The term “stiffness” or “rigidity” as used herein refers to the degree to which a material is deformed by an external force. The stiffness as applied in the present disclosure refers to the degree to which a material, i.e., the electroadhesive device, is deformed by various types of external forces, such as tension (stretching), compression (pressing), shear (twisting, layer slippage), and bending.

The polycationic ionomer constituting the anion exchange membrane 200 may include a polymer backbone and a cationic functional group bonded as a side chain to the polymer backbone.

The polymer backbone may be at least one selected from the group consisting of vinyl-based polymers, aryl-based polymers, thiazole-based polymers, pyrazole-based polymers, pyrrole-based polymers, aniline-based polymers, and thiophene-based polymers, and may be non-cross-linked or cross-linked.

The cationic functional group may be an organic basic aromatic cationic group or non-aromatic cationic group having 3 to 20 carbon atoms.

The organic basic aromatic cationic group having 3 to 20 carbon atoms may be a nitrogen (N)-containing heteroaromatic cationic group having 3 to 20 carbon atoms. For example, it may be an organic basic heteroaromatic cationic group having a nitrogen atom, such as pyridinium (Pyr⁺), imidazolium (Im⁺), pyrazolium (Pyraz⁺), triazolium (Tri⁺), purinium (Pur⁺), or quinolinium (Quinol⁺).

Additionally, the basic non-aromatic cationic group having 3 to 20 carbon atoms may be a nitrogen (N)-containing heteroaliphatic group or heteroalicyclic group having 3 to 20 carbon atoms. For example, it may be a basic non-aromatic cationic group having a nitrogen atom, such as —NCH₃⁺, piperidium (Piperi⁺), pyrrolidium (Pyrroli⁺), or pyrazolidium (Pyrazoli⁺).

More specifically, the polycationic ionomer constituting the anion exchange membrane 200 may include a polycation represented by Chemical Formula 1 below:

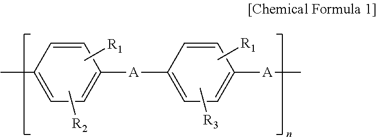

wherein R₁ [symbol] R₂ are each independently an alkyl group having 1 to 5 carbon atoms, R₃ is a substituted or unsubstituted organic basic aromatic or non-aromatic group having 3 to 20 carbon atoms, A is oxygen (O) or sulfur (S), and n is an integer from 2 to 1,000,000.

Furthermore, when R₃ is the substituted organic basic aromatic cationic group or non-aromatic cationic group, R₃ has at least one alkyl group having 1 to 5 carbon atoms as a substituent.

The polycationic ionomer represented by Chemical Formula 1 may include a counter anion such as F⁻, Br⁻, Cl⁻, or OH⁻.

The polycationic ionomer may have a glass transition temperature (Tg) of 65 to 90° C.; and a Young's modulus of 0.4 to 0.6 GPa as tested according to ASTM D638 at a speed of 1 mm/min. By satisfying the glass transition temperature and Young's modulus within the above range, the electroadhesive device can have a higher maximum allowable load (maximum allowable force, force capacity) and secure the mechanical robustness and stability of the device.

The polyanionic ionomer constituting the cation exchange membrane 300 may include a polymer backbone and an anionic functional group bonded as a side chain to the polymer backbone.

The polymer backbone may be at least one selected from the group consisting of vinyl-based polymers, aryl-based polymers, alkylene-based polymers, ether-based polymers, thioether-based polymers, and amine-based polymers, and may be non-cross-linked or cross-linked.

The anionic functional group may be —SO₃⁻, —COO⁻, or —PO₃H⁻.

More specifically, the polyanionic ionomer constituting the cation exchange membrane may include a polyanion represented by Chemical Formula 2 below:

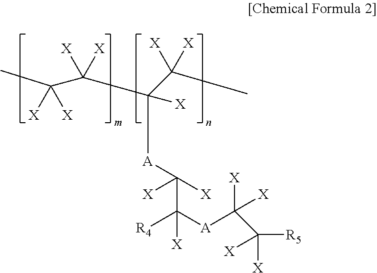

wherein R₄ is a substituted or unsubstituted alkyl group having 1 to 5 carbon atoms, R₅ is —SO₃⁺, —COO⁺, or —PO₃H⁺, A is oxygen (O) or sulfur (S), X is F, Br, or Cl, and m and n are each independently integers from 2 to 1,000,000.

The polyanionic ionomer represented by Chemical Formula 2 may include a counter cation such as H⁺.

The polyanionic ionomer may have a glass transition temperature of 100 to 150° C.; and a Young's modulus of 0.05 to 0.25 GPa as tested according to ASTM D638 at a speed of 1 mm/min.

By having the Young's modulus and glass transition temperature within the above range, the electroadhesive device can have a higher maximum allowable load (maximum allowable force, force capacity) and secure the mechanical robustness and stability of the device.

The electroadhesive device according to one embodiment of the present disclosure can be manufactured from a thermoplastic polymer without a separate cross-linking process by including an ionomer having less than 15 mol % of ionic monomer units among ionomer monomers, and can maintain a hard state even at room temperature because its glass transition temperature (T_{g}) is higher than room temperature.

Furthermore, the polycationic ionomer and polyanionic ionomer constituting the electroadhesive device according to the present disclosure can exhibit significantly improved mechanical properties compared to an ionoelastomer which has very low glass transition temperatures and thus high elasticity, and have the advantage of exhibiting low adhesive force in the off state and high adhesive force in the on state to maximize the difference in adhesive force, and of inducing smooth sliding between the adhered materials particularly in the off state. The aforementioned characteristics enable the electroadhesive device according to the present disclosure to offer the advantages of better precision control and repeated use.

According to one embodiment of the present disclosure, a metal-based electrode or a carbon-based electrode may be applied to the first electrode or the second electrode in order to increase capacitance asymmetry and to reduce resistance during deposition with the anion exchange membrane/cation exchange membrane.

The metal-based electrode may be an electrode including at least one selected from the group consisting of gold, platinum, silver, copper, aluminum, nickel, zinc, and titanium, and the carbon-based electrode may be at least one selected from the group consisting of natural graphite, graphene, fullerene, nanoribbons, porous carbon, and carbon nanotubes.

The electroadhesive device according to one embodiment of the present disclosure includes a polycationic ionomer and a polyanionic ionomer in a heterojunction structure, thereby significantly reducing operating voltage.

### Method for Manufacturing an Electroadhesive Device

According to one aspect of the present disclosure, there is provided a method for manufacturing an electroadhesive device, the method including the steps of: forming a first electrode on one surface of an anion exchange membrane; forming a second electrode on one surface of a cation exchange membrane; and joining the other surface of the anion exchange membrane and the other surface of the cation exchange membrane.

The matters described above for the electroadhesive device are likewise applied to the electroadhesive device mentioned in the manufacturing method, unless contradictory.

More specifically, in the step of forming a first electrode on one surface of the anion exchange membrane, the anion exchange membrane may be formed by dispersing a polycationic ionomer in a first solvent to prepare a dispersion, applying the dispersion on the first electrode, and drying the dispersion at 30 to 50° C. for 1 to 36 hours. Alternatively, the polycationic ionomer may be dispersed in a first solvent to prepare a dispersion; the dispersion may be applied on a glass substrate and dried to prepare an anion exchange membrane; a first electrode may be thermally deposited onto the anion exchange membrane; and the polycationic ionomer membrane may be thermally deposited onto the first electrode.

The first solvent is a solvent in which the polycationic ionomer is insoluble, and may be an alcohol having 1 to 4 carbon atoms.

Next, in the step of forming a second electrode on one surface of the cation exchange membrane, the cation exchange membrane may be formed by dispersing a polyanionic ionomer in a second solvent to prepare a dispersion, applying the dispersion on the second electrode, and drying the dispersion at 30 to 50° C. for 1 to 36 hours. Alternatively, the polyanionic ionomer may be dispersed in a second solvent to prepare a dispersion; the dispersion may be applied on a glass substrate and dried to prepare a cation exchange membrane; a second electrode may be thermally deposited onto the cation exchange membrane; and the polyanionic ionomer membrane may be thermally deposited onto the second electrode.

The second solvent is a solvent in which the polyanionic ionomer is insoluble, and may be an alcohol having 1 to 4 carbon atoms.

Next, in the step of joining the other surface of the anion exchange membrane and the other surface of the cation exchange membrane, the other surface of the anion exchange membrane having the first electrode formed on one surface and the other surface of the cation exchange membrane having the second electrode formed on one surface may be joined by simply contacting the other surface of the anion exchange membrane and the other surface of the cation exchange membrane, and then adjusting the contact force of the junction according to an applied voltage.

The method for manufacturing an electroadhesive device according to one embodiment of the present disclosure can manufacture an electroadhesive device by forming a heterojunction between the polyanionic ionomer and the polycationic ionomer through a simple process.

### Electrostatic Clutch Including an Electroadhesive Device

According to one aspect of the present disclosure, there is provided an electrostatic clutch including: the above electroadhesive device; substrates positioned on both surfaces of the electroadhesive device; a tunnel-shaped guide surrounding the substrates; and elastomer layers respectively attached to the upper and lower portions of the guide and stacked on the surfaces of the substrates.

The matters described above for the electroadhesive device are likewise applied to the electroadhesive device included in the electrostatic clutch, unless contradictory.

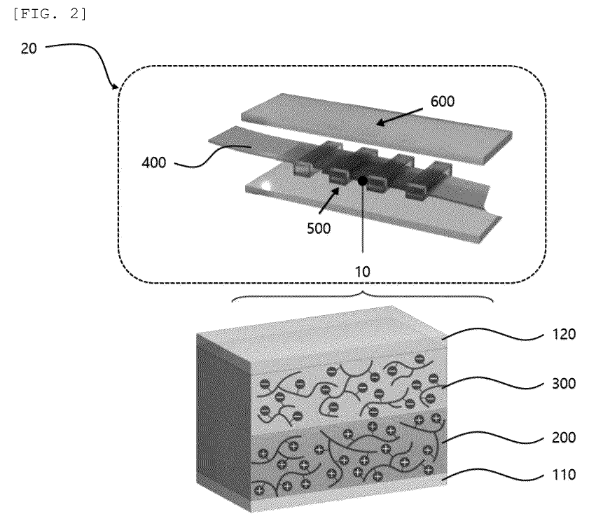

FIG. 2 is an image schematically illustrating an electrostatic clutch 20 including an electroadhesive device 10 according to one embodiment of the present disclosure.

As shown in FIG. 2, the electrostatic clutch 20 according to the present disclosure may include: substrates 400 coated on both surfaces of the electroadhesive device 10, a guide 500 formed as a plurality of tunnels to fix the movement path of the substrates 400, and elastomer layers 600 attached to the guide 500 and stacked on the surfaces of the substrates 400.

More specifically, the substrate coated on both surfaces of the electroadhesive device may be a conductive substrate in which a conductive material is coated on a base.

The base may be a plastic base including at least one selected from the group consisting of polyethylene terephthalate (PET), polyethylene naphthalate (PEN), polycarbonate (PC), polypropylene (PP), polyamide (PI), and polydimethylsiloxane (PDMS), or may be a glass base, and the conductive material may be at least one selected from the group consisting of indium tin oxide (ITO), fluorine-doped tin oxide (FTO), ZnO—Ga₂O₃, ZnO—Al₂O₃, [symbol] SnO₂—Sb₂O₃.

The substrate may be formed with a thickness of 0.1 to 0.5 mm and have a Young's modulus of 1.0 to 5.0 GPa, so that the electrostatic clutch can exhibit a high maximum allowable load (maximum allowable force, force capacity). Here, the Young's modulus is a Young's modulus as tested by ASTM D638 at a speed of 1 mm/min.

In the present disclosure, the tunnel-shaped guide surrounding the substrate may be spaced apart at preset intervals in the longitudinal direction of the substrate, and may be in the form of a plurality of tunnels.

Furthermore, the guide may fix the position of the substrate when the elastomer layer is stretched and contracted. More specifically, when the elastomer layer is repeatedly stretched and contracted, the substrate may deviate from the preset position, so the guide can set the position of the substrate by fixing the movement path of the substrate.

In the present disclosure, the elastomer layer surrounding the guide may have a form that surrounds both one surface and the other surface of the guide.

Furthermore, the elastomer layer may include a thermoplastic elastomer, wherein the thermoplastic elastomer may be at least one selected from the group consisting of a polyamide-based elastomer, a polyester-based elastomer, a polypropylene-based elastomer, a polyurethane-based elastomer, a polyolefin-based elastomer, and a polystyrene-based elastomer.

The elastomer layer has ductility, which not only ensures uniform compliance of the electrostatic clutch, but also allows the electrostatic clutch to be returned to its original position for repeated use.

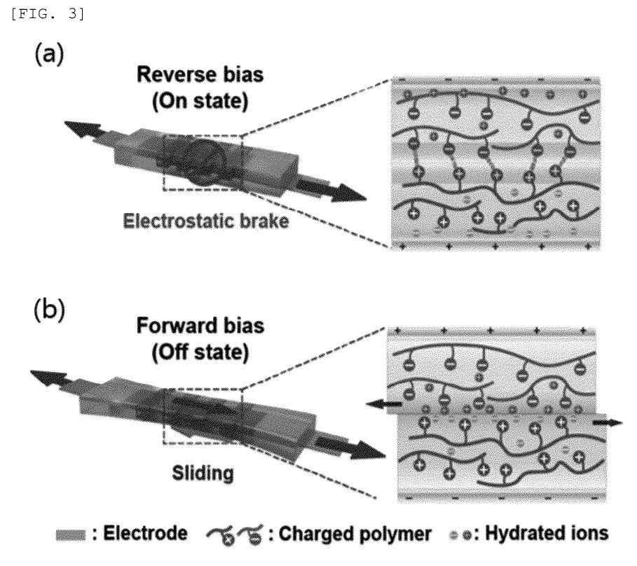

FIG. 3 is an image schematically illustrating the operating mechanism of an electrostatic clutch including an electroadhesive device according to one embodiment of the present disclosure.

Referring to (a) of FIG. 3, when a reverse bias is applied, the counter ions of the polyanionic ionomer and the polycationic ionomer drift to form an ionic double layer (IDL) at the junction of the cation exchange membrane and the anion exchange membrane, and an electrostatic attraction between the oppositely charged polyanionic ionomer and the polycationic ionomer is generated to prevent the electrode from slipping, thereby increasing the stiffness of the electrostatic clutch according to the present disclosure.

Referring to (b) of FIG. 3, when a forward bias is applied, the counter ions of the polyanionic ionomer and polycationic ionomer accumulate at the junction between the cation exchange membrane 300 and the anion exchange membrane 200 to block an electrostatic attraction between the oppositely charged polyanionic ionomer and polycationic ionomer, thereby allowing the electrostatic clutch according to the present disclosure to freely slide and move depending on the stiffness of the elastomer layer, i.e., the degree of deformation of the elastomer layer.

The electrostatic clutch according to one embodiment of the present disclosure employs the electroadhesive device having the heterojunction structure of the polyanionic ionomer and polycationic ionomer, and thus, can exhibit low adhesion and mechanical robustness and adjust the stiffness of the device depending on the forward and reverse directions of electric current.

### Application of the Electrostatic Clutch

According to one embodiment of the present disclosure, a device or system including the electrostatic clutch is provided.

According to one embodiment of the present disclosure, the device including the electrostatic clutch may be a haptic device or a tactile feedback device.

In the present disclosure, the haptic device is a device that provides tactile feedback to a user to offer an experience as if something is actually touched or felt during interaction with a digital device or a virtual environment, wherein an electrostatic clutch may play a key role for precise and fast tactile feedback.

According to one embodiment of the present disclosure, the system including the electrostatic clutch may be a precision position control system, a robot actuator system, an electrostatic friction application system, or the like.

In the present disclosure, the precision position control system may be semiconductor manufacturing equipment, an optical system such as a precision lens, a nanopositioning system, or the like. The robot actuator system may be a microrobot using a MEMS system, a servo mechanism, a joint actuator of a humanoid, or the like. The electrostatic friction application system may be a touch- or friction-based artificial muscle system, an electrostatic drive-based smart system, or the like.

Hereinafter, the present disclosure will be described in more detail by way of preferred examples. However, these examples are for illustrating the present disclosure more specifically, and it will be apparent to those skilled in the art that the scope of the present disclosure is not limited by these examples.

### Example 1. Manufacture of Electroadhesive Device 1

In order to increase the capacitance asymmetry between the electric double layer (EDL) and the ionic double layer (IDL), microporous carbon electrodes (ELAT 1400, Fuel Cell Store) were used as first and second electrodes, respectively. A polycationic ionomer (FAD-55, Fuel Cell Store) represented by Chemical Formula 1A below was dispersed in ethanol and applied onto the first electrode. In addition, a 20% ethanol dispersion of a polyanionic ionomer represented by Chemical Formula 2A below (Nafion D2020 dispersion, Fuel Cell Store) was applied onto the second electrode. In this case, the thicknesses of the applied polycationic ionomer and polyanionic ionomer were each formed to be 50 μm or less. The first and second electrodes, on which the polycationic ionomer dispersion and the polyanionic ionomer dispersion were respectively applied, were dried at room temperature for 6 hours and then dried in a vacuum oven at 40° C. for 24 hours to form an anion exchange membrane and a cation exchange membrane on the first and second electrodes, respectively. Then, the other surface of the anion exchange membrane and the other surface of the cation exchange membrane were simply brought into contact to manufacture an electroadhesive device 1 having a heterojunction structure according to the present disclosure.

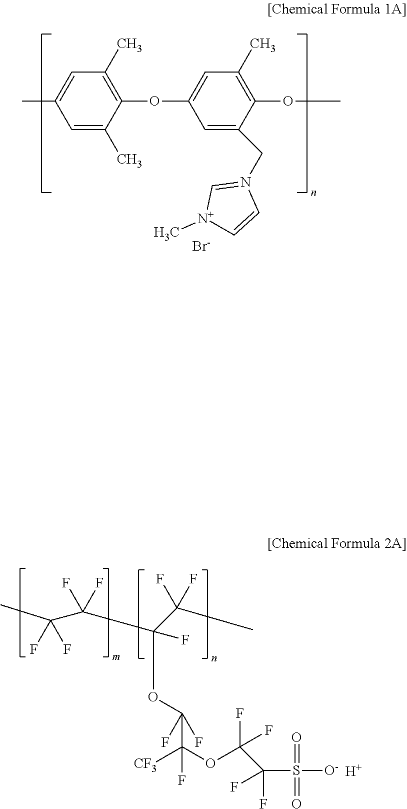

### Example 2. Manufacture of Electroadhesive Device

In order to improve adhesive force with the ionomer exchange membrane, gold (Au) was used as first and second electrodes, respectively. A polycationic ionomer membrane (FAD-55, Fuel Cell Store) represented by Chemical Formula 1A above was immersed in a 1.0 wt % KBr solution for 24 hours, washed with deionized water, and dried in a vacuum oven at 40° C. to prepare an anion exchange membrane. The anion exchange membrane was thermally deposited onto the first electrode. In addition, the polyanionic ionomer membrane represented by Chemical Formula 2A above was stored in water for 24 hours and dried in a vacuum oven to prepare a cation exchange membrane. The cation exchange membrane was thermally deposited onto the second electrode. The other surface of the anion exchange membrane and the other surface of the cation exchange membrane were simply brought into contact to manufacture an electroadhesive device 2 having a heterojunction structure according to the present disclosure.

### Example 3. Manufacture of Electrostatic Clutch 1

Both surfaces of the electroadhesive device 1 prepared in Example 1 were fixed to substrates (thickness: 0.132 mm) including an ITO-coated PET base using a cyanoacrylate superglue. Then, a tunneling guide including a plurality of tunnels was formed on the substrate at a preset distance, and both surfaces of the guide were surrounded with a soft elastomer (3M, VHB Tape) to form an elastomer layer, thereby manufacturing an electrostatic clutch 1 according to the present disclosure.

### Example 4. Manufacture of Electrostatic Clutch 2

An electrostatic clutch 2 according to the present disclosure was manufactured in the same manner as in Example 3, except that the electroadhesive device 2 manufactured in Example 2 was applied.

### Experimental Example 1. Confirmation of Ionomer Properties

### 1.1. Thermal Properties of Ionomers

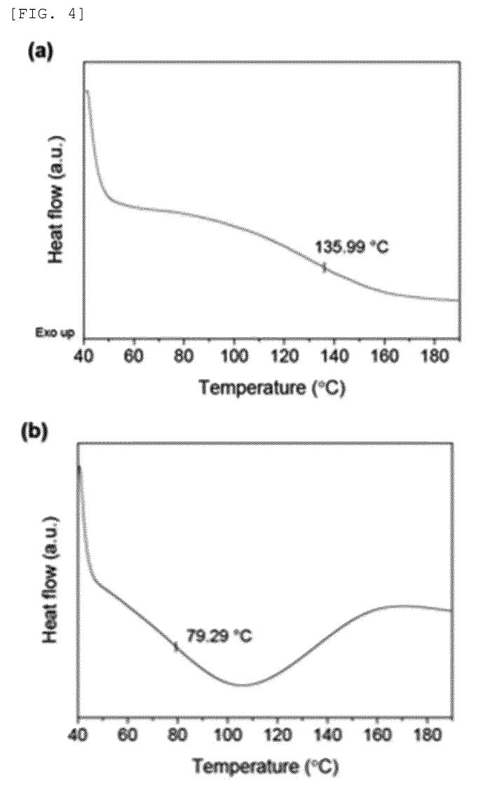

In order to confirm the thermal properties of the polyanionic ionomer and the polycationic ionomer applied in the present disclosure, a differential scanning calorimetry (DSC) was performed on the polyanionic ionomer represented by Chemical Formula 1A and the polycationic ionomer represented by Chemical Formula 2A used in Examples 1 and 2, respectively, and the results are shown in FIG. 4.

(a) of FIG. 4 is a DSC graph for the polyanionic ionomer represented by Chemical Formula 1A, confirming that it has a glass transition temperature of 135.99° C. (b) of FIG. 4 is a DSC graph for the polycationic ionomer represented by Chemical Formula 2A, confirming that it has a glass transition temperature of 79.29° C.

### 1.2. Mechanical Properties of Ionomers

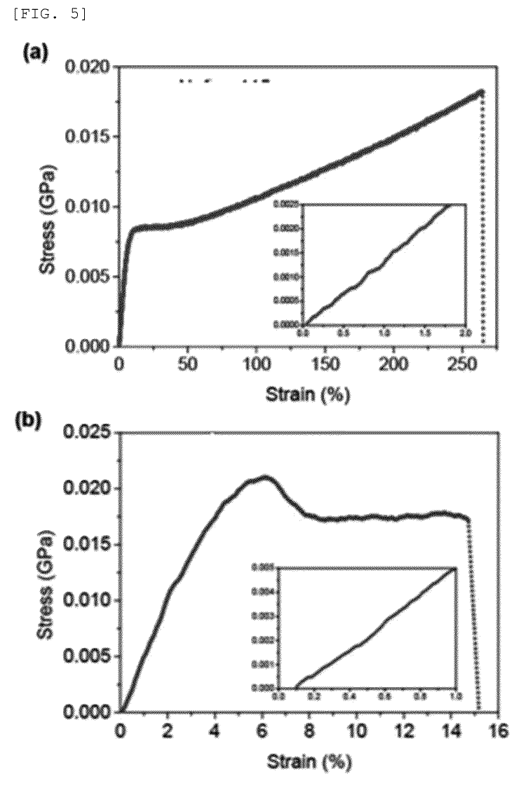

In order to confirm the mechanical properties of the polyanionic ionomer and the polycationic ionomer applied in the present disclosure, uniaxial tensile tests (Instron 3360, performed at a speed of 1 mm/min) were performed on the polyanionic ionomer represented by Chemical Formula 1A and the polycationic ionomer represented by Chemical Formula 2A used in Examples 1 and 2. In the uniaxial tensile test, the polyanionic ionomer and the polycationic ionomer were cut into a dog-bone shape (ASTM D638 Type 4) using a laser cutter (VLS2.30DT, ULS), and then measured three times to derive an average value, from which stress-strain curves were plotted, and the results are as shown in FIG. 5.

(a) of FIG. 5 is a graph for the polyanionic ionomer represented by Chemical Formula 1A above, and it can be confirmed that the polyanionic ionomer has a Young's modulus of 0.13 GPa and an elongation at break of about 265%. (b) of FIG. 5 is a graph for the polycationic ionomer represented by Chemical Formula 2A above, and it can be confirmed that the polycationic ionomer has a Young's modulus of 0.53 GPa and an elongation at break of about 15%.

### Experimental Example 2. Confirmation of Adhesive Force of the Junction

In order to confirm the adhesive force of the junction between the anion exchange membrane and the cation exchange membrane in the electroadhesive device according to the present disclosure, the adhesive force of the anion exchange membrane/anion exchange membrane (red), the cation exchange membrane/cation exchange membrane (blue), and the anion exchange membrane/cation exchange membrane (black) according to the applied voltage was confirmed by measuring the load (P) according to the displacement (5) using a texture analyzer (TA.XT PlusC, Stable Micro Systems).

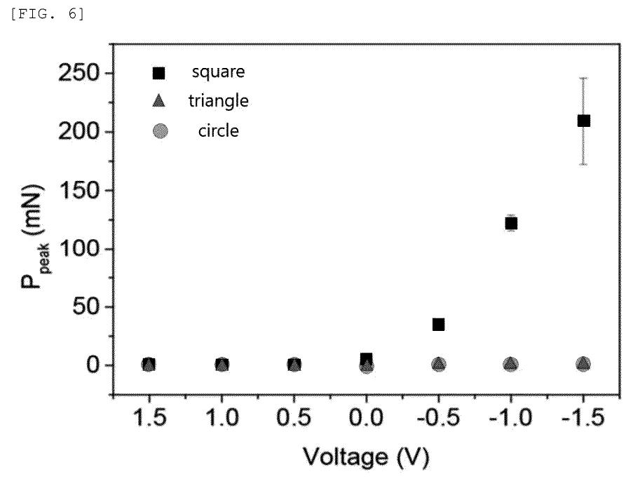

More specifically, first, the anion exchange membrane and cation exchange membrane were each cut into rectangular shapes (10 mm×40 mm) and then attached to cylinder jigs, respectively, to prepare a cation exchange membrane jig and an anion exchange membrane jig. The cation exchange membrane jig was secured above the texture analyzer, and the anion exchange membrane jig was secured below the texture analyzer. Then, the cation exchange membrane jig was moved at a speed of 0.01 mm/sec, and when the load was 50 mN, it had a dwell time of 60 seconds after stopping. Then, it was moved at a speed of 0.01 mm/sec to measure the load when detached, and the results are as shown in FIG. 6.

Referring to FIG. 6, the adhesive forces between the anion exchange membrane/anion exchange membrane (triangle) and the cation exchange membrane/cation exchange membrane (circle), i.e., the homojunctions, showed insensitive behavior to the applied voltage, and exhibited adhesive forces of 2.07±0.04 mN and 1.1±0.13 mN, respectively. On the other hand, it can be confirmed that the junction between the anion exchange membrane/cation exchange membrane (square), i.e., the heterojunction according to the present disclosure, has an adhesive force similar to that of the homojunctions under a forward voltage, and an adhesive force of 200 mN or more under a reverse voltage. Through the above results, it can be confirmed that the heterojunction structure manufactured according to the present disclosure can have a greater difference in adhesive force depending on the applied voltage.

### Experimental Example 3. Confirmation of the Operating Mechanism

In order to confirm the operating mechanism of the electroadhesion between the ionomers forming the anion exchange membrane and the cation exchange membrane in the electroadhesive device according to the present disclosure, a reference 620 instrument (Gamry Instruments) was used to measure the AC impedance for the heterojunction of the high-surface-area carbon electrode under various DC biases using the electroadhesive device 1 manufactured in Example 1.

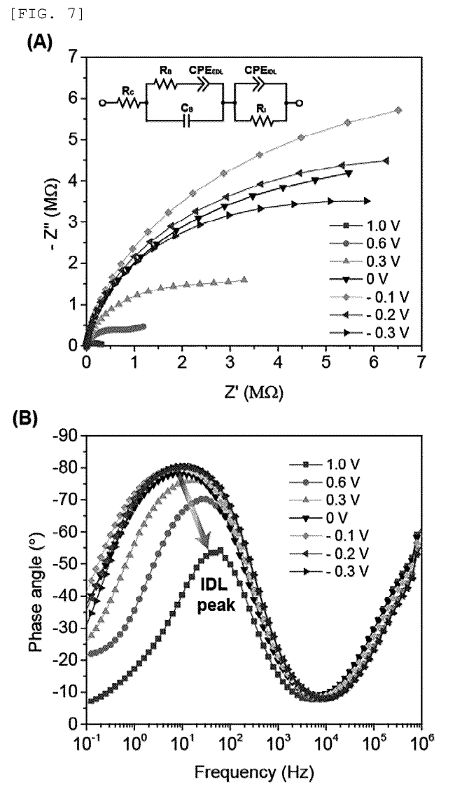

More specifically, the measurement was performed at a DC voltage of ±1.0 V, a frequency in the range of 1 MHz to 0.1 Hz, and an amplitude of 40 mV by connecting the working electrode to the cation exchange membrane and the counter/reference electrode to the anion exchange membrane. The measured results were fitted using ZView software (Scribner Associates, version 3.5 h) to derive the required results, and the results are shown in FIG. 7.

Referring to FIG. 7, it can be confirmed that (a) the semicircle of the Nyquist plot and (b) the phase angle peak corresponding to the ionic double layer (IDL) disappear when a forward bias is applied. From the above results, it can be seen that under the forward bias, the IDL exhibits resistive behavior as counter-ions accumulate at the interface, and the phase angle peak decreases as the forward bias increases.

Therefore, it can be said that when the electroadhesive device according to the present disclosure forms an ionic double layer (IDL), strong electrostatic adhesion is possible between the heterojunctions of the oppositely charged ionomers at low voltage, suggesting that it can be applied as a high-performance low-voltage electrostatic clutch.

### Experimental Example 4. Confirmation of Force Capacity Per Unit Contact Area

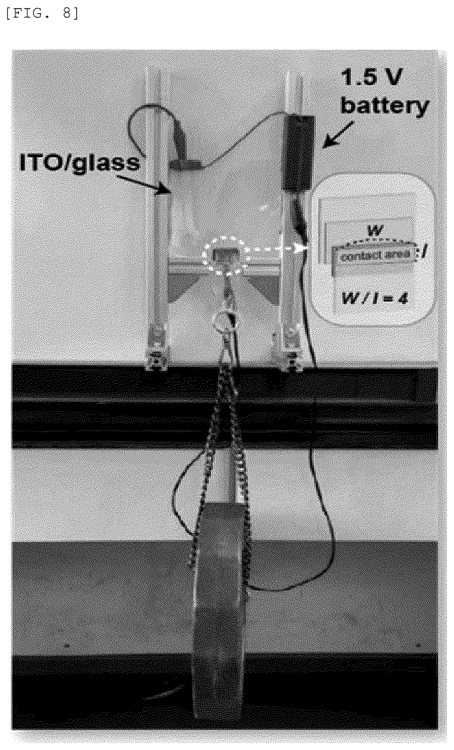

In order to confirm the force capacity per unit contact area of the electroadhesive device according to the present disclosure, the electroadhesive device 2 manufactured in Example 2 was attached to a high-elasticity substrate (ITO/glass), and 5 kg of weight was coupled to confirm the force while supplying a constant applied voltages of +1.5 V and −1.5 V in a contact area of 1 cm² (2 cm wide, 0.5 cm long), and the results are shown in FIG. 8.

Referring to FIG. 8, it can be confirmed that the electroadhesive device according to the present disclosure can lift a 5 kg weight when a reverse bias of −1.5 V was applied to a contact area of 1 cm² at a constant voltage (using a 1.5 V battery). From the above results, it can be seen that a strong force is generated due to electrostatic attraction at the junction between the anion exchange membrane and the cation exchange membrane under reverse bias.

### Experimental Example 5. Confirmation of Electrostatic Clutch Stiffness

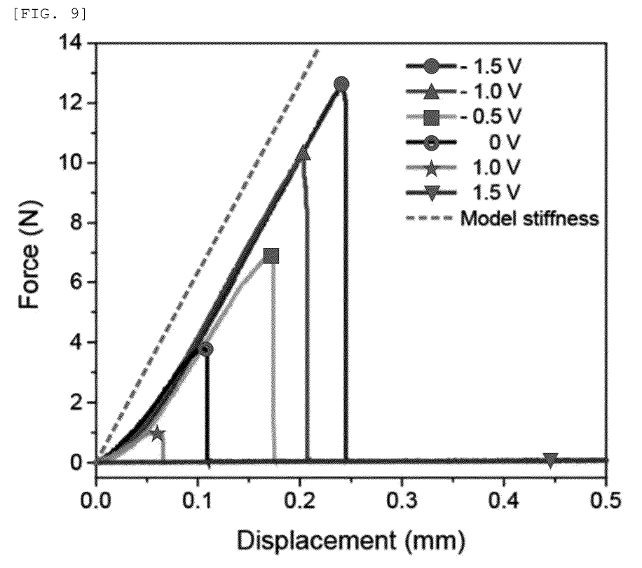

In order to confirm the overall stiffness of the electrostatic clutch according to the present disclosure, i.e., the degree to which the electrostatic clutch according to the present disclosure is deformed by an external force, for the electrostatic clutch 2 manufactured in Example 4 above, the force (F) according to the displacement (δ) (0.02 mm/sec) was measured using a texture analyzer (TA.XT PlusC, Stable Micro Systems) at −1.5 V to +1.5 V and RH 30% to plot a force-displacement curve, and the results are as shown in FIG. 9.

Referring to FIG. 9, it can be confirmed that when the electrostatic clutch according to the present disclosure is in an activated state (on state) in which it is engaged, the electroadhesive device according to the present disclosure exhibits a total stiffness of 62×10³ N/m, which is the sum of the slope values of −0.5 V, −1.0 V, and −1.5 V. This may indicate that in an inactive state (off state), the electrostatic clutch does not generate contact force, allowing it to slide smoothly, ultimately following the stiffness of the elastomer layer, and the stiffness when +1.5 V is applied in the off state is approximately 530 times or more lower than that when −1.5 V is applied in the on state. In addition, the yield strength of the electrostatic clutch according to the present disclosure may be adjusted according to the applied voltage. For example, it can be confirmed that when the reverse bias increases from 0 V to −1.5 V, the yield strength, which is the shear stress that can be expressed as load (P)/cross-sectional area (A) in the load-displacement curve, increases from 38 kPa to 126 kPa. This means that the strength of the electrostatic clutch can be effectively programmed by changing the voltage.

### Experimental Example 6. Confirmation of Electrostatic Clutch Reversibility

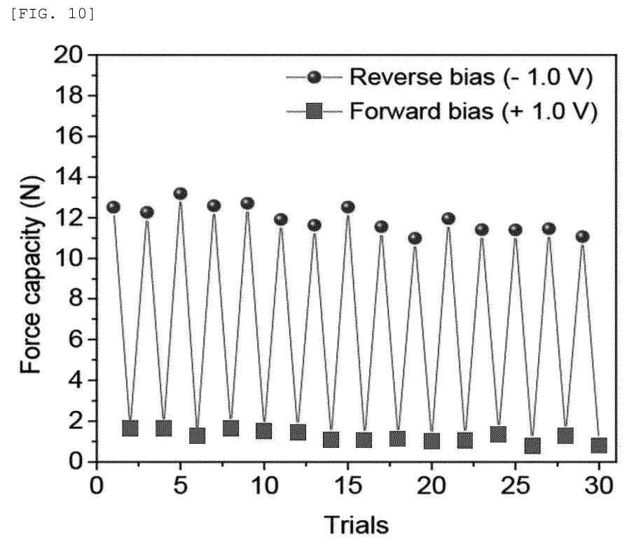

In order to confirm the reversibility of the electrostatic clutch according to the present disclosure, for the electrostatic clutch 2 manufactured in Example 4, durability under cyclic loading at room temperature, 50% RH, and a DC voltage of ±1.0 V was tested through repetitive lap shear tests to confirm the force capacity (Fc), which means the maximum force that the electrostatic clutch can withstand without being destroyed or permanently deformed, and the results are shown in FIG. 10.

Referring to FIG. 10, it can be confirmed that in 30 or more repeated experiments, the electrostatic clutch according to the present disclosure has a force capacity (Fc) of 11.95±0.64 N in the reverse voltage state (−1 V, blue) and a consistent force capacity (Fc) value of 1.30±0.27 N in the forward voltage state (+1 V, red). The above results suggest that the electrostatic clutch according to the present disclosure has robust stability and consistency, exhibits reliable reversibility, and may be practically applied in various applications requiring precise control and repeated use.

From the above description, those skilled in the art to which the present disclosure pertains will understand that the present disclosure may be embodied in other specific forms without changing the technical spirit or essential characteristics thereof. In this regard, it should be understood that the embodiments described above are illustrative in all respects and not restrictive.

What is claimed is:

1. An electroadhesive device comprising:
an anion exchange membrane comprising a polycationic ionomer;
a first electrode formed on one surface of the anion exchange membrane;
a cation exchange membrane comprising a polyanionic ionomer; and
a second electrode formed on one surface of the cation exchange membrane,
wherein the other surface of the anion exchange membrane and the other surface of the cation exchange membrane are joined to each other to form a heterojunction structure.

2. The electroadhesive device of claim 1, wherein the polycationic ionomer comprises a polymer backbone and a cationic functional group bonded as a side chain to the polymer backbone,
wherein the polymer backbone is at least one selected from the group consisting of vinyl-based polymers, aryl-based polymers, thiazole-based polymers, pyrazole-based polymers, pyrrole-based polymers, aniline-based polymers, and thiophene-based polymers, which are non-cross-linked or cross-linked, and
the cationic functional group is an organic basic aromatic cationic group or non-aromatic cationic group having 3 to 20 carbon atoms.

3. The electroadhesive device of claim 2, wherein the polycationic ionomer comprises a polycation represented by Chemical Formula 1 below: 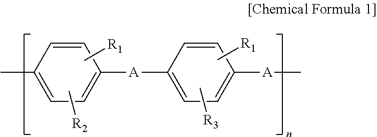
wherein:
R₁ and R₂ are each independently an alkyl group having 1 to 5 carbon atoms,
R₃ is a substituted or unsubstituted organic basic aromatic cationic group or non-aromatic cationic group having 3 to 20 carbon atoms,
A is oxygen (O) or sulfur (S),
n is an integer from 2 to 1,000,000, and
when R₃ is the substituted organic basic aromatic cationic group or non-aromatic cationic group, R₃ has at least one alkyl group having 1 to 5 carbon atoms as a substituent.

4. The electroadhesive device of claim 1, wherein the polyanionic ionomer comprises a polymer backbone and an anionic functional group bonded as a side chain to the polymer backbone,
wherein the polymer backbone is at least one selected from the group consisting of vinyl-based polymers, aryl-based polymers, alkylene-based polymers, ether-based polymers, thioether-based polymers, and amine-based polymers, which are non-cross-linked or cross-linked, and
and the anionic functional group is —SO₃⁻, —COO⁻, or —PO₃H⁻.

5. The electroadhesive device of claim 4, wherein the polyanionic ionomer comprises a polyanion represented by Chemical Formula 2 below: 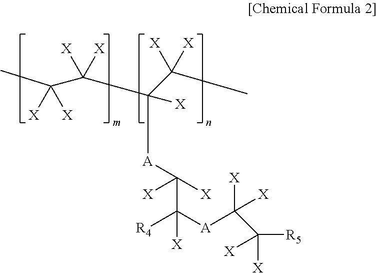
wherein:
R₄ is a substituted or unsubstituted alkyl group having 1 to 5 carbon atoms,
R₅ is —SO₃⁻, —COO⁻, or —PO₃H⁻,
A is oxygen (O) or sulfur (S),
X is F, Br, or Cl, and
m and n are each independently integers from 2 to 1,000,000.

6. The electroadhesive device of claim 1, wherein the polycationic ionomer has a glass transition temperature (Tg) of 65 to 90° C.; and a Young's modulus of 0.4 to 0.6 GPa as tested according to ASTM D638 at a speed of 1 mm/min.

7. The electroadhesive device of claim 1, wherein the polyanionic ionomer has a glass transition temperature (Tg) of 100 to 150° C.; and a Young's modulus of 0.05 to 0.25 GPa as tested according to ASTM D638 at a speed of 1 mm/min.

8. The electroadhesive device of claim 1, wherein the first electrode and the second electrode are each independently a metal-based electrode or a carbon-based electrode,
wherein the metal-based electrode comprises at least one selected from the group consisting of gold, platinum, silver, copper, aluminum, nickel, zinc, and titanium, and
the carbon-based electrode comprises at least one selected from the group consisting of natural graphite, graphene, fullerene, nanoribbons, porous carbon, and carbon nanotubes.

9. A method for manufacturing the electroadhesive device of claim 1, the method comprising the steps of:
forming a first electrode on one surface of an anion exchange membrane;
forming a second electrode on one surface of a cation exchange membrane; and
joining the other surface of the anion exchange membrane and the other surface of the cation exchange membrane to each other.

10. An electrostatic clutch comprising:
the electroadhesive device of claim 1;
substrates positioned on both surfaces of the electroadhesive device;
a tunnel-shaped guide surrounding the substrates; and
elastomer layers respectively attached to the upper and lower portions of the guide and stacked on the surfaces of the substrates.

11. The electrostatic clutch of claim 10, wherein the guide is in the form of a plurality of tunnels spaced apart in the longitudinal direction of the substrate.
